(19) United States
(12) Patent Application Publication
(10) Pub. No.: US 2024/0379896 A1
(43) Pub. Date: Nov. 14, 2024

(54) SUBSTRATE PROCESSING SYSTEM FOR MANUFACTURING TANDEM CELL STRUCTURES

(71) Applicant: Applied Materials, Inc., Santa Clara, CA (US)

(72) Inventors: Shinobu Abe, Toyonaka-shi (JP); Scott Yongkee Chae, San Ramon, CA (US); Shinichi Kurita, San Jose, CA (US); Duoyan Shen, Mountain View, CA (US)

(21) Appl. No.: 18/656,825

(22) Filed: May 7, 2024

Related U.S. Application Data
(60) Provisional application No. 63/465,044, filed on May 9, 2023.

(51) Int. Cl. H01L 31/20; H01L 31/0224; H01L 31/043

(52) U.S. Cl. CPC H01L 31/20; H01L 31/022425; H01L 31/043

(57) ABSTRACT

A substrate processing system includes two or more process tools including multiple process chambers to perform a corresponding substrate processing procedure and a substrate transport to transport substrates between the two or more process tools. The system further includes a control system to cause one or more first layers to be deposited on a substrate in one or more first process chambers to form a first cell of a tandem cell structure. The control system is further to cause the substrate to be transported from the one or more first process chambers to one or more second process chambers. A combination process tool includes the one or more second process chambers. The control system is further to cause one or more second layers to be deposited on the substrate in the one or more second process chambers to form a second cell of the tandem cell structure.

### RELATED APPLICATIONS

This application claims the benefit of U.S. Provisional Patent Application No. 63/465,044 filed May 9, 2023, the entire contents of which are incorporated by reference herein.

### TECHNICAL FIELD

The instant specification generally relates to electronic device fabrication. More specifically, the instant specification relates to manufacturing tandem cell structures.

### BACKGROUND

Various deposition techniques are commonly used to deposit layers (such as thin film layers) on substrates. For effective deposition of layers, different deposition techniques can be used depending on the material to be deposited and/or based on the end product.

Solar cells can be made up of multiple layers of different materials deposited on a substrate.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with at least one embodiment, a substrate processing system is provided. The substrate processing system includes two or more process tools including a plurality of process chambers configured to perform a corresponding substrate processing procedure. The substrate processing system further includes a substrate transport configured to transport substrates between the two or more process tools. The substrate processing system further includes a control system. The control system is to cause one or more first layers to be deposited on a substrate in one or more first process chambers of the two or more process tools to at least partially form a first cell of a tandem cell structure. The control system is further to cause the substrate to be transported from the one or more first process chambers to one or more second process chambers of the two or more process tools. A combination process tool of the two or more process tools includes the one or more second process chambers. The control system is further to cause one or more second layers to be deposited on the substrate in the one or more second process chambers to at least partially form a second cell of the tandem cell structure.

In accordance with at least one embodiment, a system is provided. The system includes one or more first process chambers configured to deposit one or more first layers on a substrate to at least partially form a first cell of a tandem cell structure. The system further includes one or more second process chambers configured to deposit one or more second layers on the substrate to at least partially form a second cell of the tandem cell structure. The system further includes a substrate transport configured to transport the substrate between the one or more first process chambers and the one or more second process chambers.

In accordance with at least one embodiment, a method is provided. The method includes depositing one or more first layers on a substrate in one or more first process chambers to at least partially form a first cell of a tandem cell structure. The method further includes transporting the substrate from the one or more first process chambers to one or more second process chambers. The method further includes depositing one or more second layers on the substrate in the one or more second process chambers to at least partially form a second cell of the tandem cell structure.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIGS. 1A-1B are schematic views of an example substrate processing system, in accordance with some embodiments.

FIG. 2 is a cutaway side-view of an example solar cell array, in accordance with some embodiments.

FIGS. 3A-3D are cutaway side-views of an example in-process substrate, in accordance with some embodiments.

FIGS. 4A-4B are cutaway side views of an example in-process substrate, in accordance with some embodiments.

FIGS. 5A-5E are cutaway side views of an example in-process substrate, in accordance with some embodiments.

FIGS. 6A-6B are cutaway side views of an example in-process substrate, in accordance with some embodiments.

FIGS. 7A-7B are cutaway side views of an example in-process substrate, in accordance with some embodiments.

FIG. 8 is a flow chart of an example method for processing a substrate, in accordance with some embodiments.

FIG. 9 is a block diagram illustrating a computer system, in accordance with some embodiments.

### DETAILED DESCRIPTION

In substrate processing, deposition techniques are used to deposit layers (e.g., thin film layers) on substrates. Over multiple deposition procedures, multiple layers can be built up on a substrate to form a device such as an electronics device, a display device, a solar cell device, etc. Deposition procedures used to deposit layers on a substrate often vary. In some examples, deposition of a particular material can be accomplished by a specific deposition technique. Deposition of another material can be accomplished by another specific deposition technique. Some deposition techniques in common use are chemical vapor deposition (CVD), physical vapor deposition (PVD), and evaporation. In CVD processes, a substrate is exposed to one or more volatile vapor precursors which react and/or decompose on the substrate surface to produce a deposited layer. In PVD processes, a substrate is exposed to one or more volatile solid precursors which react on the substrate surface to produce a deposited layer. Evaporation processes are a sub-class of PVD processes where source material is evaporated in a vacuum and delivered directly to the substrate where the source material condenses back to a solid state to produce a deposited layer. Because of the differences involved between different deposition techniques, process chambers are often produced and set up to perform only one type of deposition technique. Products that include layers deposited by different deposition techniques are produced using multiple different process chambers.

A solar cell (e.g., photovoltaic cell) is an electronic device that converts the energy of light into electricity by the photovoltaic effect. Light from a source, such as the sun, excites electrons in a semiconductor material of the solar cell which flow into conducting electrodes and produce electric current. Individual solar cells are often combined to form a solar array (e.g., a photovoltaic array, a solar array, etc.). Solar cells are often based on a crystal silicon substrate that undergoes various processing procedures. Conventionally, solar cells include a single cell having multiple layers deposited on the silicon substrate. These conventional single cell solar cells often have an efficiency of approximately 25%. In some embodiments, the efficiency of a solar cell can be increased by instead utilizing a tandem cell structure. In some embodiments, a second cell is added to a first cell to form the tandem cell structure. The second cell may be added on top of the first cell. In some embodiments, the second cell is based on one or more deposited perovskite layers. Perovskite may be a calcium titanium oxide mineral composed of calcium titanate (CaTiO₃). Perovskite may be made of inorganic and/or organic material. In some embodiments, by manufacturing a solar cell with a tandem cell structure (e.g., having a first cell based on a silicon substrate and a second cell based on one or more perovskite layers), efficiency of the solar cell can be increased to approximately 32% or more.

In some embodiments, solar cells having a tandem cell structure as described herein include multiple material layers that can be deposited by multiple deposition processes (e.g., CVD, PVD, evaporation, etc.). The multiple deposition processes to manufacture a tandem cell structure may be performed in multiple different processing chambers. In some embodiments, the processing of substrates to form first and second cells of a tandem cell structure can be performed by a single manufacturing system to streamline manufacturing. In some embodiments, a manufacturing system for tandem cell structures is described herein.

In some embodiments, a manufacturing system for tandem cell structures includes multiple (e.g., two or more) process tools (e.g., clusters of process chambers, groups of process chambers, etc.). In some embodiments, each process tool includes one or more process chambers coupled to a central chamber such as a transfer chamber and/or a mainframe. The one or more process chambers of the multiple process tools may each be configured to deposit a respective layer on a substrate by a respective deposition procedure such as a chemical vapor deposition (CVD) procedure, a physical vapor deposition (PVD) procedure, and/or an evaporation deposition procedure. Each process tool may further include a factory interface (e.g., an EFEM) coupled to the mainframe. The process chambers of each process tool may be disposed around the periphery of the central chamber and may be coupled thereto. In some embodiments, the process chambers of a process tool are configured to perform one or more deposition processes. In some embodiments, all process chambers of a first process tool are configured to perform a first deposition process and all process chambers of a second process tool are configured to perform a second deposition process. In some embodiments, one or more first process chambers of a process tool are configured to perform a first deposition process and one or more second process chambers of the process tool are configured to perform a second deposition process.

In some embodiments, a manufacturing system for tandem cell structures includes a substrate transport to transport substrates between different process tools. In some embodiments, the substrate transport delivers substrates to an interface (e.g., an EFEM) of a first process tool where one or more first processing operations are performed on the substrates. The substrate transport may receive the processed substrates and deliver the substrates to a second process tool for further processing. The substrate transport may receive the further processed substrates and deliver the substrates to another process tool or to a final delivery area for finished product. The substrate transport may include a conveyor, one or more rails, a suspension system (e.g., an overhead suspension system), and/or a maglev system. In some embodiments, the substrate transport can transport multiple substrates at a time. In some examples, the substrate transport transports substrate carriers (e.g., wafer carriers, etc.) from an EFEM of a first cluster of process chambers to an EFEM of a second cluster. In some embodiments, the substrate transport includes a substrate flipper (e.g., a substrate flipping mechanism such as a robot, etc.) to flip substrates in transit between process tools. The substrates may be flipped so that processing operations can be performed with respect to a first side of the substrate and/or to a second side of the substrate.

In some embodiments, a manufacturing system for tandem cell structures includes a control system. The control system may be made up of one or more processing devices to control various components of the manufacturing system. In some embodiments, the control system is to cause the manufacturing system to perform various tasks, procedures, and/or processes to manufacture tandem cell structures.

In some embodiments, the control system is to cause the deposition of layers on a substrate to form a first cell of a tandem cell structure. The control system may cause the substrate to be introduced into one or more first process chambers of one or more first process tools. In some examples, the control system may cause the substrate transport to deliver the substrate to an EFEM of a first process tool and further cause one or more substrate transport robots to place the substrate in a process chamber. A first deposition process may be performed with respect to the substrate to form a first layer on the substrate and a second deposition process may be performed to form a second layer on the substrate. In some embodiments, the controller causes one or more of a CVD process, a PVD process, and/or an evaporation deposition process to be performed with respect to the substrate to form the first cell of the tandem cell structure. The substrate may be transferred between process chambers (e.g., by a substrate transfer robot) within the process tool to receive different deposition layers.

In some embodiments, the control system is to cause transportation of the substrate from the one or more first process chambers (e.g., of the one or more first process tools) to one or more second process chambers (e.g., of one or more second process tools). In some examples, the control system may control the substrate transport to convey the substrate from an EFEM of a first process tool to an EFEM of a second process tool. In some embodiments, the control system causes a substrate carrier to be transported along a transport path from a first process tool to a second process tool. In some embodiments, the control system causes the substrate to be flipped (e.g., flipped from a first orientation to a second orientation, flipped over, etc.). The substrate may be flipped while en route to another process operation (e.g., in another process tool).

In some embodiments, the control system is to cause the deposition of layers on the substrate to form a second cell of the tandem cell structure. The control system may cause the substrate (e.g., the processed substrate having the one or more first deposition layers) to be introduced into one or more second process chambers of one or more second process tools. A third deposition process may be performed with respect to the substrate to form a third layer on the substrate and a fourth deposition process may be performed to form a fourth layer on the substrate. In some embodiments, the controller causes one or more of an additional CVD process, a PVD process, and/or an evaporation deposition process to be performed with respect to the substrate to form the second cell of the tandem cell structure. In some embodiments, at least one of the layers of the second cell is a perovskite layer. In some embodiments, the perovskite layer is deposited by an evaporation deposition process. Once finished, the tandem cell structure may be transferred out of the one or more second process chambers and transported away (e.g., for packaging, for shipment, etc.).

Aspects and implementations of the present disclosure result in technological advantages over other approaches. For example, manufacturing tandem cell structures using a system disclosed herein results in a continuous process without undue interruption, resulting in increased manufacturing throughput. In another example, all manufacturing processes for a tandem cell structure can be controlled by a single control system, resulting in more consistent and/or higher quality processed substrates. Accordingly, improved tandem cell structures can be manufactured at a faster rate and/or more cheaply than by another approach.

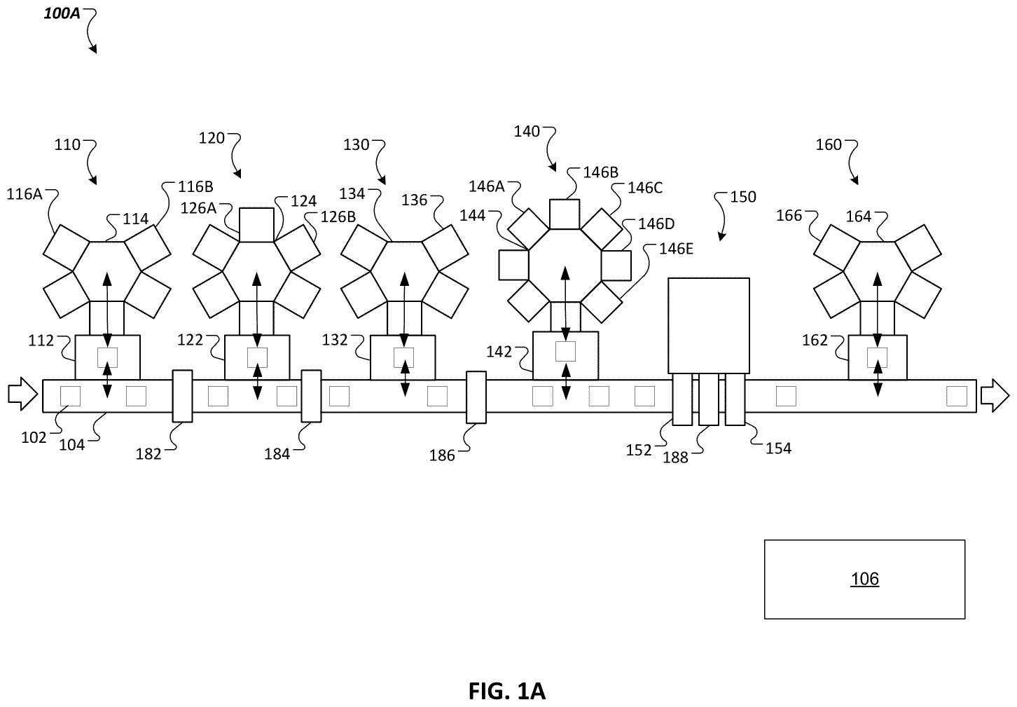

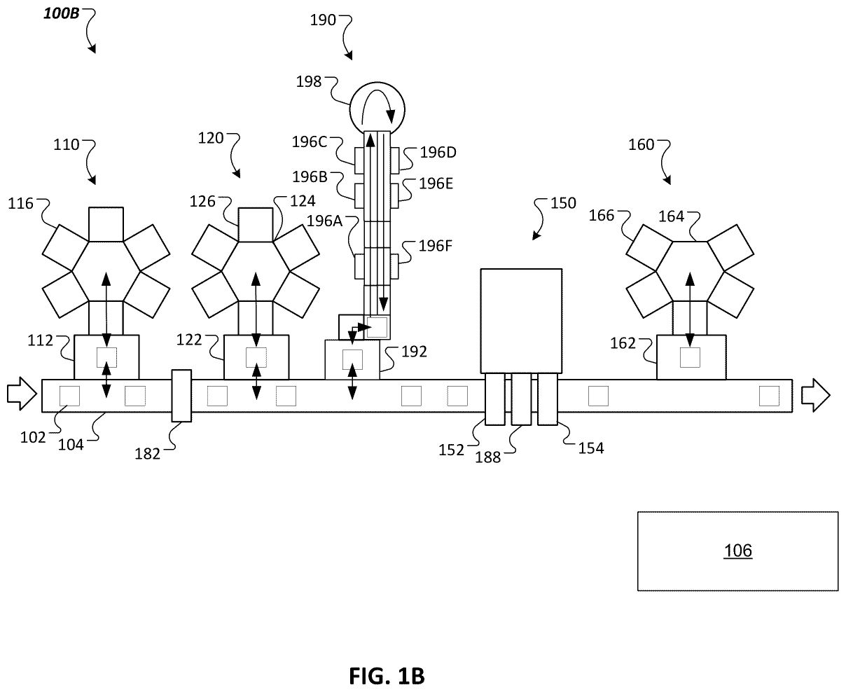

FIGS. 1A-1B are schematic views of an example substrate processing system, in accordance with some embodiments. FIG. 1A shows an example substrate processing system 100A for manufacturing tandem cell structures, in accordance with some embodiments. FIG. 1B shows an example substrate processing system 100B for manufacturing tandem cell structures, in accordance with some embodiments. Features shown in FIG. 1B having similar naming and/or numbering to features described with respect to FIG. 1A may have similar structure and/or function.

Referring to FIG. 1A, substrate processing system 100A includes multiple process tools (e.g., multiple clusters of process chambers) and a substrate transport for transporting substrates between the multiple clusters. In some embodiments, a first cell of a tandem cell structure is manufactured in clusters 110, 120, and/or 130. In some embodiments, a second cell of a tandem cell structure is manufactured in cluster 140. Printing system 150 and cluster 160 may add further layers to the tandem cell structure.

In some embodiments, a controller 106 controls the operations of system 100A, including the operations of the multiple clusters of process chambers and/or the operations of the substrate transport. In some embodiments, a substrate 102 is provided to the substrate transport 104. The substrate 102 may be provided inside a substrate carrier that may be carrying multiple substrates. The substrate transport 104 may be configured to transport a substrate carrier to transport multiple substrates at a time. In some embodiments, the substrate transport 104 is a conveyor (e.g., having a conveyor belt), an overhead transport, a rail-based transport, and/or a maglev system for transporting substrate carriers. In some embodiments, multiple substrates are put into a carrier by an overhead system. In some embodiments, the substrate transport 104 includes a network of transport robots to transport substrate carriers. In some embodiments, the substrate transport 104 is a maglev system that can transport substrate carriers along one or more maglev paths between clusters of process chambers.

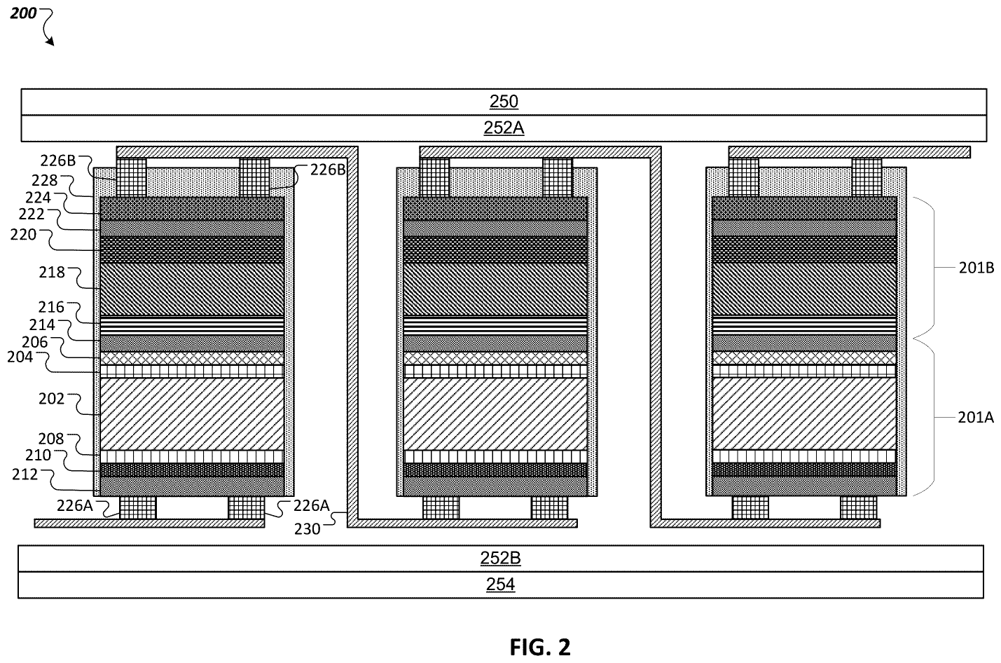

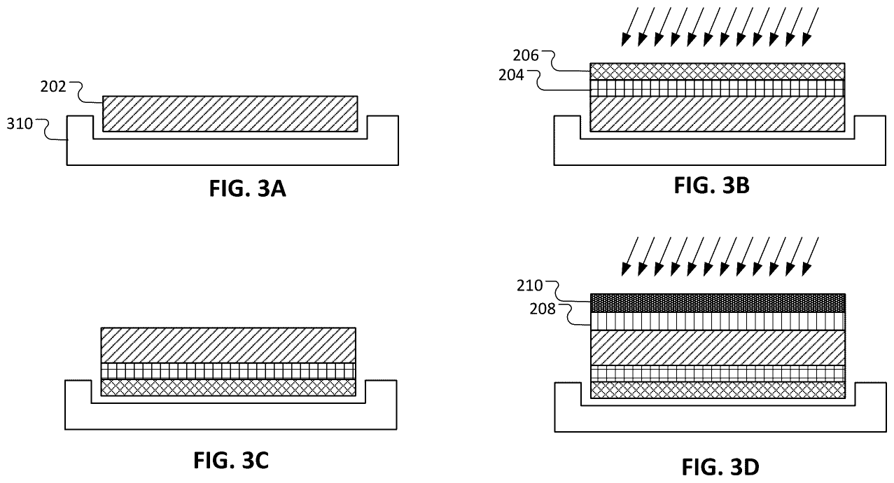

In some embodiments, substrate transport 104 delivers substrate 102 (e.g., substrate 202 of FIG. 2) to a first cluster of process chambers 110. First cluster 110 may be a first process tool. In some embodiments, a substrate carrier carrying substrate 102 docks with an interface chamber 112 (e.g., an EFEM). In some embodiments, substrate 102 is delivered to the first cluster 110 carried in a first substrate tray (e.g., tray 320 of FIGS. 3A-3B). The first tray may support the substrate 102 during transport and/or during transfer inside the first cluster 110 (e.g., between chambers, etc.). Substrate 102 may be retrieved from the carrier (e.g., by a substrate transfer robot) and introduced into transfer chamber 114 through a load lock. Substrate 102 may be supported by the first tray while transferred inside the first cluster 110. In some embodiments, substrate 102 is moved into a process chamber of cluster 110. In some embodiments, all process chambers of cluster 110 are to perform the same substrate processing procedure. In some embodiments, process chambers of cluster 110 are to perform different substrate processing procedures.

In some embodiments, substrate 102 is transferred into process chamber 116A (e.g., by a substrate transfer robot) for the performance of a first substrate processing procedure. In some embodiments, one or more layers are deposited on substrate 102 inside process chamber 116A. In some embodiments, process chamber 116A performs a CVD process to deposit a first layer of amorphous silicon (e.g., layer 204 of FIG. 2) on a top side of the substrate 102. In some embodiments, substrate 102 is transferred from process chamber 116A to process chamber 116B (e.g., via a substrate transfer robot in transfer chamber 114). In some embodiments, process chamber 116B performs a second deposition process with respect to substrate 102. In some embodiments, process chamber 116B performs a CVD process to deposit a second layer of amorphous silicon (e.g., layer 206 of FIG. 2) on a top side of the substrate 102 (e.g., on top of the first layer of amorphous silicon). Subsequent to the process procedure performed with respect to the substrate 102 in process chamber 116B, substrate 102 may be transferred out of cluster 110 to the substrate transport 104. In some embodiments, a substrate transfer robot places substrate 102 (e.g., together with a first substrate supporting tray) in a substrate carrier docked with interface chamber 112.

In some embodiments, substrate transport 104 transports substrate 102 from the first cluster 110 to the second cluster 120. Second cluster 120 may be a second process tool. In some embodiments, a substrate flipper 182 flips substrate 102 as substrate 102 is transported. Substrate flipper 182 may include a substrate transfer robot configured to flip one or more substrates. In some embodiments, substrate flipper 182 removes substrate 102 from a carrier, flips substrate 102 from a first orientation to a second orientation (e.g., flips substrate 102 upside-down), and places substrate 102 in another substrate carrier. In some embodiments, substrate flipper 182 unloads substrate 102 from a first tray and loads substrate 102 onto a second tray (e.g., tray 320 of FIGS. 3C-3D). The first tray may be re-used for supporting an additional substrate for processing in cluster 110. In some embodiments, substrate flipper 182 is configured to flip multiple substrates at a time. In some examples, substrate flipper 182 may include multiple robot end-effectors for flipping multiple substrates.

In some embodiments, substrate transport 104 delivers substrate 102 upside-down to the second cluster of process chambers 120. A carrier carrying substrate 102 on a second tray may dock with interface chamber 122. Substrate 102 (supported by the second tray) may be retrieved from the carrier and introduced into the transfer chamber 124 (e.g., via a load lock chamber). In some embodiments, substrate 102 is transferred into a process chamber 126A for a first substrate processing procedure. In some embodiments, a third layer of amorphous silicon (e.g., layer 208 of FIG. 2) is deposited on the bottom side of substrate 102 in process chamber 126A by CVD. In some embodiments, substrate 102 is transferred from process chamber 126A to process chamber 126B (e.g., via a substrate transfer robot in transfer chamber 124) for a second substrate processing procedure. In some embodiments, a fourth layer of amorphous silicon (e.g., layer 210 of FIG. 2) is deposited on the bottom side of substrate 102 (e.g., on top of the first layer of amorphous silicon) by CVD. Subsequent to the process procedure (e.g., deposition procedure) performed with respect to substrate 102 in process chamber 126B, substrate 102 may be transferred out of cluster 120 to the substrate transport 104. In some embodiments, a substrate transfer robot places substrate 102 (e.g., together with a second substrate supporting tray) in a substrate carrier docked with interface chamber 122.

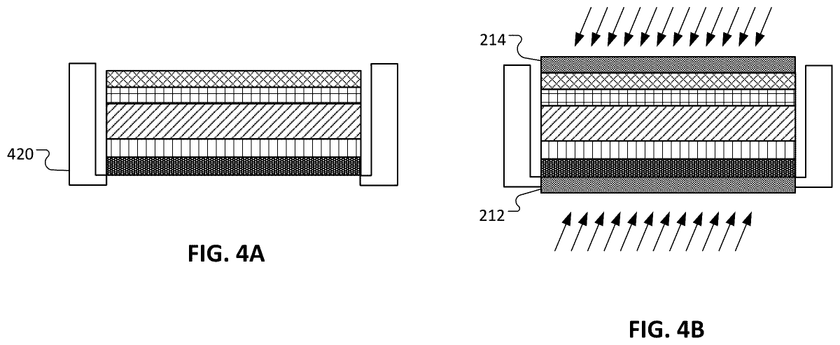

In some embodiments, substrate transport 104 transports substrate 102 from second cluster 120 to a third cluster of process chambers 130. Third cluster 130 may be a third process tool. In some embodiments, a substrate flipper 184 flips substrate 102 as substrate 102 is transported. In some embodiments, substrate flipper 184 picks substrate 102 from a second tray in an upside-down orientation and places substrate 102 in a third tray (e.g., tray 420 of FIGS. 4A-4B) in a topside-up orientation. In some embodiments, the second tray is configured for supporting substrate 102 in a CVD process and the third tray is configured for supporting substrate 102 in a PVD process. The third tray may have a gridded structure that supports substrate 102 along the edges of substrate 102. For example, the third tray may include a window that exposes the surface of substrate 102 so that one or more layers can be deposited on the substrate 102 (e.g., during a deposition process inside a process chamber). In some embodiments, the third tray includes an electrostatic chuck that can induce an electric charge to electrostatically fasten substrate 102 to the third tray. In some embodiments, the third tray includes a battery to wirelessly power the electrostatic chuck.

In some embodiments, substrate transport 104 delivers substrate 102 topside-up to the third cluster 130. A carrier carrying substrate 102 may dock with interface chamber 132. Substrate 102 (supported by the third tray) may be retrieved from the carrier and introduced into the transfer chamber 134 (e.g., via a load lock chamber). In some embodiments, substrate 102 is transferred into a process chamber 136 for a substrate processing procedure. In some embodiments, a first layer of indium tin oxide (ITO) (e.g., layer 212 of FIG. 2) is deposited on substrate 102 inside a process chamber 136 of third cluster 130. The layer of ITO may be deposited by PVD inside the chamber. In some embodiments, substrate 102 is removed from process chamber 136 and flipped upside-down (together with the third supporting tray). Substrate 102 is then provided to another process chamber (or the same process chamber) of third cluster 130 to receive a second layer of ITO (e.g., layer 214 of FIG. 2) by PVD. Subsequent to the deposition of an ITO layer on both the top side and the bottom side, substrate 102 is removed from the third cluster 130. In some embodiments, the first cell of the tandem cell structure is complete when the deposition of ITO on both the top side and the bottom side is finished. In some embodiments, substrate 102 is transferred from the third cluster 130 to a substrate carrier docked to the interface chamber 132.

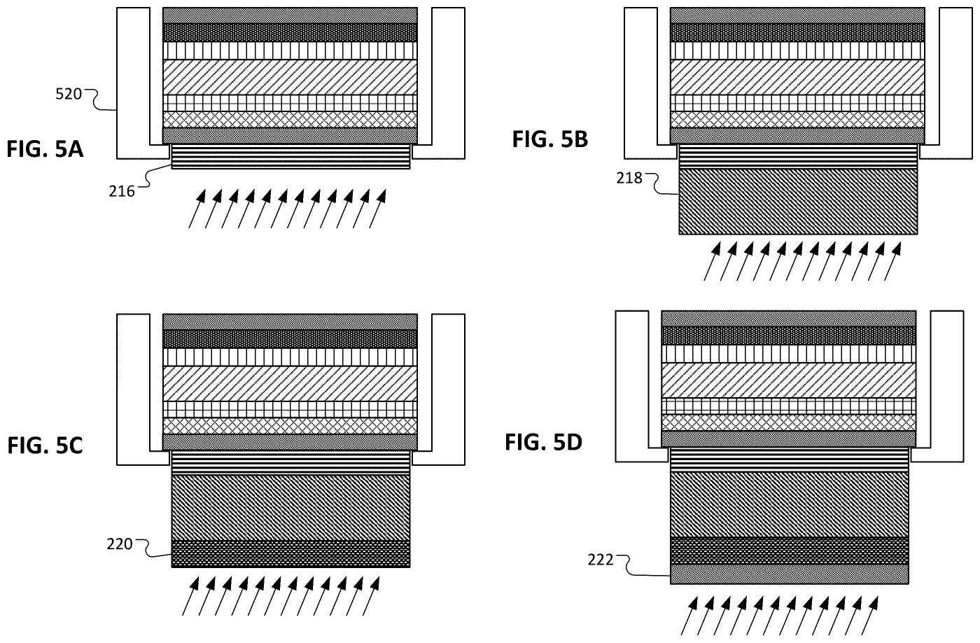

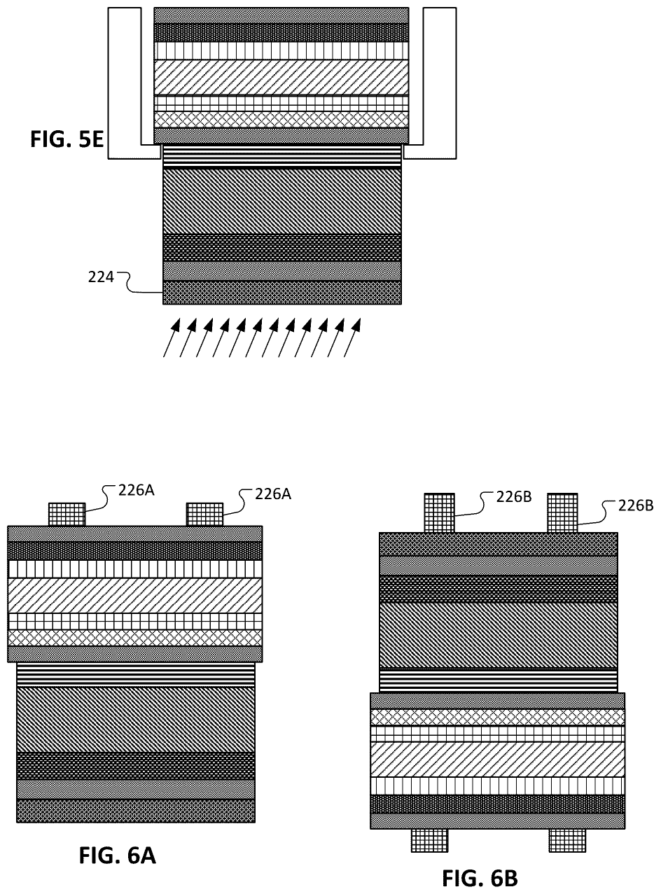

In some embodiments, substrate transport 104 transports substrate 102 from the third cluster 130 to a fourth cluster of process chambers 140. Fourth cluster 140 may be a fourth process tool. Fourth cluster 140 may be a combination cluster of process chambers having multiple process chambers to perform multiple different substrate processing procedures. In some embodiments, a substrate flipper 186 flips substrate 102. Substrate flipper 186 may include a substrate transfer robot configured to flip one or more substrates. In some embodiments, substrate flipper 186 removes substrate 102 from a carrier, flips substrate 102 to an upside-down orientation, and places substrate 102 into another carrier. Substrate 102 may already be in an upside-down orientation, in which case substrate flipper 186 does not flip substrate 102, and instead merely picks substrate 102 from a first carrier and places substrate 102 in another carrier. In some embodiments, substrate flipper 186 removes substrate 102 from a third tray configured to support substrate 102 during a PVD process to a fourth tray (e.g., tray 520 of FIGS. 5A-5E) configured to support substrate 102 during an evaporation deposition process. In some embodiments, the fourth tray includes an electrostatic chuck that can induce an electric charge to electrostatically retain substrate 102 to the fourth tray responsive to activation of the chuck. In some embodiments, the fourth tray includes a battery to wirelessly power the electrostatic chuck.

In some embodiments, substrate transport 104 delivers substrate 102 upside-down to the fourth cluster 140. In some embodiments, fourth cluster 140 includes multiple process chambers 146 each configured to perform evaporation deposition and/or PVD. In some embodiments, a substrate carrier carrying substrate 102 may dock with interface chamber 142. Substrate 102 (supported by a fourth tray) may be retrieved from the carrier and introduced into the transfer chamber 144 (e.g., via a load lock chamber). The transfer chamber 144 may include a substrate transfer robot to transfer substrate 102 into and out of various chambers coupled to the transfer chamber 144, such as process chambers 146A-E, etc. In some embodiments, substrate 102 is transferred into a process chamber 146A to receive a hole transport layer (HTL) (e.g., layer 216 of FIG. 2). In some embodiments, substrate 102 receives HTL by evaporation deposition in process chamber 146A. HTL may be a layer deposited on substrate 102 to block electron flux. In some embodiments, substrate 102 is transferred into a process chamber 146B to receive a perovskite layer (e.g., layer 218 of FIG. 2). The perovskite layer may be deposited on substrate 102 by evaporation deposition in process chamber 146B. In some embodiments, substrate 102 is transferred into a process chamber 146C to receive an electron transport layer (ETL) (e.g., layer 220 of FIG. 2). In some embodiments, substrate 102 receives ETL by evaporation deposition in process chamber 146C. ETL may be a layer deposited on substrate 102 to facilitate electron transportation. In some embodiments, substrate 102 is transferred into a process chamber 146D to receive a buffer layer (e.g., layer 222 of FIG. 2). The buffer layer may be deposited by evaporation onto substrate 102. In some embodiments, substrate 102 is transferred into a process chamber 146E to receive a layer of indium zinc oxide (IZO) (e.g., layer 224 of FIG. 2). In some embodiments, the IZO layer is deposited onto substrate 102 by PVD. In some embodiments, layers deposited onto substrate 102 in process chambers 146A-E are deposited on top of one another. In some embodiments, the layers are deposited depo-up, meaning the layers are deposited on a lower surface of substrate 102 inside the process chamber. However, the layers may be deposited on a top surface of substrate 102 because substrate 102 may be upside-down during deposition. In some embodiments, cluster 140 includes a substrate flipper to flip substrate 102 between deposition processes. Subsequent to the deposition of the buffer layer on substrate 102, substrate 102 is removed from the fourth cluster 140. In some embodiments, the second cell of the tandem cell structure is complete when the deposition of the buffer layer is finished. In some embodiments, substrate 102 is transferred from the fourth cluster 140 to a substrate carrier docked to the interface chamber 142. In some embodiments, substrate 102 is unloaded from the fourth tray configured for evaporation deposition and/or PVD processes.

In some embodiments, substrate transport 104 transports substrate 102 from cluster 140 to printing system 150. Printing system 150 may be a metal printing sub-system for printing a metal layer on a substrate. In some embodiments, substrate 102 is provided to a first printing element 152 in an upside-down orientation. Printing element 152 may print an electrode layer (e.g., electrodes 226A of FIG. 2) on the bottom side of substrate 102 to form one or more metal electrodes. A substrate flipper 188 may then flip substrate 102 to a topside-up orientation. Substrate 102 may be provided to a second printing element 154 in the topside-up orientation. Printing element 154 may print an electrode layer (e.g., electrodes 226B of FIG. 2) on the top side of substrate 102 to form one or more metal electrodes.

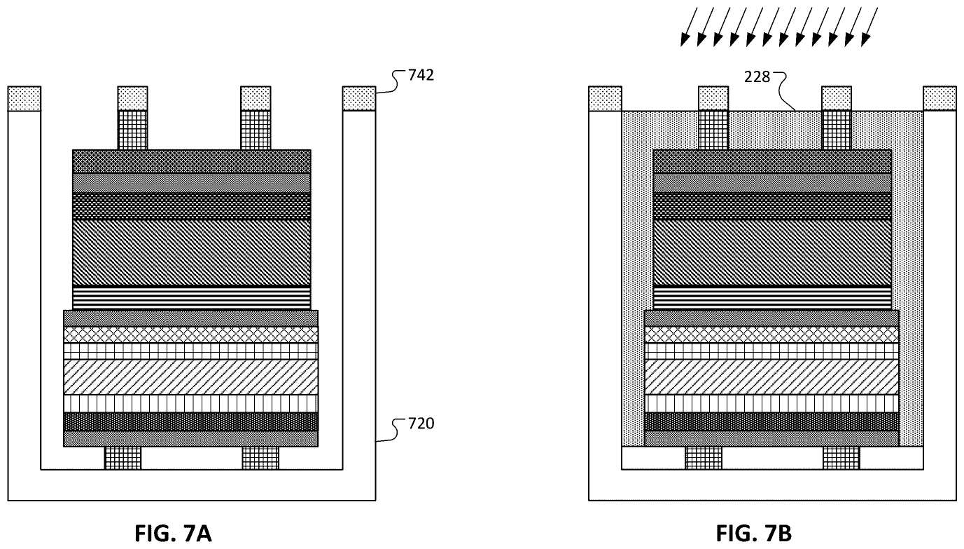

In some embodiments, substrate transport 104 transports substrate 102 to cluster 160. Cluster 160 may be a process tool. In some embodiments, substrate 102 is loaded into a fifth tray (e.g., tray 720 of FIGS. 7A-7B). A carrier carrying substrate 102 may dock with interface chamber 162. Substrate 102 (supported by the fifth tray) may be retrieved from the carrier and introduced into the transfer chamber 164 (e.g., via a load lock chamber). In some embodiments, substrate 102 is transferred into process chamber 166 for a deposition operation. In some embodiments, the fifth tray and/or electrodes on the substrate are masked before the deposition operation, either within cluster 160 or before substrate 102 is delivered to cluster 160. In some embodiments, a thin film encapsulation (TFE) layer (e.g., layer 228 of FIG. 2) is deposited on substrate 102 within process chamber 166. In some embodiments, the TFE layer is deposited by CVD. The TFE layer may encapsulate at least one surface of the tandem cell structure. In some embodiments, substrate 102 is removed from the process chamber 166 and output from the manufacturing system. The mask may be removed from the electrodes before or after substrate 102 is removed from the cluster 160.

Referring to FIG. 1B, substrate transport 104 may transport substrate 102 from second cluster 120 to inline process tool 190. Inline process tool 190 may be a combination cluster of process chambers. In some embodiments, inline process tool 190 includes multiple process chambers 196A-F for processing substrates. Process chambers 196A-F may perform functions substantially similar to clusters 130 and 140 of FIG. 1A. In some embodiments, the processing chambers 196A-F are arranged in a continuous path along which substrates can flow for processing. In some embodiments, inline process tool 190 handles substrates in a vertical orientation. Handling substrates in a vertical orientation may allow for the deposition of layers on both sides of a substrate without the need of flipping the substrate.

In some embodiments, substrates are supported by a gridded tray when processed in inline process tool 190. The tray may include a grid structure that supports the substrates by the substrate edges. The tray may include windows that expose the faces of the substrates (e.g., the top side face and the bottom side face) so that layers can be deposited on the faces of the substrates. The tray may support multiple substrates. In some embodiments, the tray includes an electrostatic chuck to hold the substrates to the tray. The electrostatic chuck may be powered by a battery onboard the tray so that the electrostatic chuck can be wirelessly powered. In some embodiments, once electrostatic charging is complete for chucking the substrate 102 on the tray, the substrate 102 may be retained on the tray.

In some embodiments, substrate 102 is provided into interface chamber 192 (e.g., retrieved from a carrier by a substrate transfer robot). In some embodiments, substrate 102 enters interface chamber 192 in a horizontal orientation. In some embodiments, substrate 102 is moved to a vertical orientation for transfer along the transfer path within inline process tool 190. In some embodiments, substrate 102 is provided along a transfer path to processing chamber 196A. In processing chamber 196A, substrate 102 may be subject to a processing operation to deposit a layer of ITO on the top side of substrate 102 (e.g., layer 214 of FIG. 2) and/or on a bottom side of substrate 102 (e.g., layer 212 of FIG. 2). In some embodiments, the layer(s) of ITO is deposited by PVD. In some embodiments, substrate 102 is transferred (e.g., in a vertical orientation) to process chamber 196B to receive an HTL (e.g., layer 216 of FIG. 2). The HTL may be deposited on substrate 102 by evaporation deposition. In some embodiments, substrate 102 is transferred to process chamber 196C to receive a perovskite layer (e.g., layer 218 of FIG. 2). The perovskite layer may be deposited on substrate 102 by evaporation deposition. In some embodiments, substrate 102 is transferred to process chamber 196D to receive an ETL (e.g., layer 220 of FIG. 2). The ETL may be deposited on substrate 102 by evaporation deposition. In some embodiments, substrate 102 is transferred to process chamber 196E to receive a buffer layer (e.g., layer 222 of FIG. 2). The buffer layer may be deposited on substrate 102 by evaporation deposition. In some embodiments, substrate 102 is transferred to process chamber 196F to receive an IZO layer (e.g., layer 224 of FIG. 2). The IZO layer may be deposited on substrate 102 by PVD. Subsequent to the deposition of the IZO layer, substrate 102 is removed from inline process tool 190. Substrate 102 may then be provided to printing system 150 (e.g., by substrate transport 104).

FIG. 2 is a cutaway side-view of an example solar cell array 200, in accordance with some embodiments. In some embodiments, solar cell array 200 includes a glass cover 250 and a bottom layer 254. The bottom layer 254 may be made up of aluminum and/or glass. Solar cell array 200 may further include epoxy layers 252A and 252B. The glass cover 250, bottom layer 254, and/or epoxy layers 252A and 252B may encapsulate multiple solar cells. In some embodiments, each solar cell includes a tandem cell structure made up of a first cell 201A and a second cell 201B. The second cell 201B may be disposed on top of the first cell 201A. In some embodiments, multiple solar cells are electrically coupled by one or more conducting traces 230. A trace 230 may be a copper conductor coupled to electrodes of neighboring solar cells.

In some embodiments, first cell 201A is made up of several material layers. Each layer may be deposited on one another and/or on a substrate 202. The substrate 202 may be a crystal silicon substrate. The substrate 202 may have a negative charge. A first amorphous silicon layer 204 may be disposed on top of the substrate 202. The first amorphous silicon layer 204 may have a neutral charge. A second amorphous silicon layer 206 may be disposed on top of the first amorphous silicon layer 204. The second amorphous silicon layer 206 may have a negative charge. A third amorphous silicon layer 208 may be disposed beneath the substrate 202. The third amorphous silicon layer 208 may have a neutral charge. A fourth amorphous silicon layer 210 may be disposed beneath the third amorphous silicon layer 208. The fourth amorphous silicon layer 210 may have a positive charge. A first ITO layer 212 may be disposed beneath the fourth amorphous silicon layer 210. A second ITO layer 214 may be disposed on top of the second amorphous silicon layer 206. The first cell 201A of the tandem cell structure may be made up of the substrate 202 and layers 204-214.

In some embodiments, second cell 201B is made up of several material layers. Each layer may be deposited on one another and/or on the first cell 201A. An HTL 216 may be disposed on top of the second ITO layer 214. A perovskite layer 218 may be disposed on top of HTL 216. An ETL 220 may be disposed on top of the perovskite layer 218. A buffer layer 222 may be disposed on top of the ETL 220. An IZO layer 224 may be disposed on top of the buffer layer 222. The second cell 201B of the tandem cell structure may be made up of layers 216-224.

In some embodiments, electrodes are disposed on top and bottom of the tandem cell structure. The electrodes may be made of a conducting metal, such as silver. Electrodes 226A may be coupled (e.g., deposited on, disposed on, etc.) to a bottom of the first cell 201A. Electrodes 226A may be coupled to the first ITO layer 212. Electrodes 226B may be coupled to a top of second cell 201B. Electrodes 226B may be coupled to the IZO layer 224. In some embodiments, a TFE layer encapsulates at least the top of the second cell 201B. The TFE layer may additionally encapsulate one or more sides of the first cell 201A and/or the second cell 201B.

FIGS. 3A-3D are cutaway side-views of an example in-process substrate, in accordance with some embodiments. Referring to FIG. 3A, in some embodiments, substrate 202 is placed on a tray 310 for processing. Referring to FIG. 3B, a first amorphous silicon layer 204 may be deposited on top of substrate 202 (e.g., in process chamber 116A of FIG. 1A). Second amorphous silicon layer 206 may be deposited on top of the first amorphous silicon layer 204 (e.g., in process chamber 116B of FIG. 1A). In some embodiments, both first amorphous silicon layer 204 and second amorphous silicon layer 206 are deposited by CVD. Layers 204 and 206 may be deposited depo-down, meaning the deposition of material is directed downward onto the substrate 202.

Referring to FIG. 3C, the substrate 202 (and layers 204 and 206) are flipped on the tray. In some embodiments, the substrate 202 is flipped by a substrate flipper (e.g., substrate flipper 182 of FIG. 1A) that may include a substrate transfer robot. Referring to FIG. 3D, a third amorphous silicon layer 208 may be deposited on the substrate 202 (e.g., in process chamber 126A of FIG. 1A). A fourth amorphous silicon layer 210 may be deposited on the third amorphous silicon layer 208 (e.g., in process chamber 126B of FIG. 1A). In some embodiments, both third amorphous silicon layer 208 and fourth amorphous silicon layer 210 are deposited by CVD. Layers 208 and 210 may be deposited depo-down.

FIGS. 4A-4B are cutaway side views of an example in-process substrate, in accordance with some embodiments. Referring to FIG. 4A, in some embodiments, the in-process substrate is flipped (e.g., by substrate flipper 184 of FIG. 1A) and placed in a tray 420. In some embodiments, tray 420 includes a window to expose the bottom of the processed substrate for further material deposition. Referring to FIG. 4B, a first ITO layer 212 is deposited on layer 210 (e.g., in process chamber 136 of FIG. 1A) and a second ITO layer 214 is deposited on layer 206 (e.g., in process chamber 136 of FIG. 1). In some embodiments, the first ITO layer 212 and the second ITO layer 214 are deposited by PVD processes. Layers 212 and 214 may be separately deposited (e.g., during separate deposition operations) or deposited during one operation. In some embodiments, layer 212 is deposited depo-up, meaning the deposition material directed upward onto layer 210. Layer 214 may be deposited depo-down.

FIGS. 5A-5E are cutaway side views of an example in-process substrate, in accordance with some embodiments. Referring to FIG. 5A, the in-process substrate may be flipped (e.g., by substrate flipper 186 of FIG. 1A) and placed in a tray 520. Tray 520 may be a gridded tray having a window to expose the surface of the in-process substrate for further material deposition. In some embodiments, tray 520 includes an electrostatic chuck to electrostatically hold the in-process substrate. The tray may include an electrostatic chuck pad to retain charging of the substrate 102 on the tray. Although tray 520 is shown holding the in-process substrate in a horizontal orientation, tray 520 may be configured to hold the in-process substrate in a vertical orientation (e.g., holding the in-process substrate at an angle 90 degrees to as shown). In some embodiments, an HTL 216 is deposited on layer 214 (e.g., in process chamber 146A of FIG. 1A). HTL 216 may be deposited by evaporation. HTL may be deposited depo-up. Referring to FIG. 5B, a perovskite layer 218 may be deposited on HTL 216 (e.g., in process chamber 146B of FIG. 1A). The perovskite layer 218 may be deposited by evaporation. The perovskite layer 218 may be deposited depo-up. Referring to FIG. 5C, an ETL 220 may be deposited on the perovskite layer 218 (e.g., in process chamber 146C of FIG. 1A). The ETL 220 may be deposited by evaporation. The ETL 220 may be deposited depo-up. Referring to FIG. 5D, a buffer layer 222 may be deposited on the ETL 220 (e.g., in process chamber 146D of FIG. 1A). The buffer layer 222 may be deposited by evaporation. The buffer layer 222 may be deposited depo-up. Referring to FIG. 5E, an IZO layer 224 may be deposited on the buffer layer 222 (e.g., in process chamber 146E of FIG. 1A). The IZO layer 224 may be deposited by PVD. The IZO layer 224 may be deposited depo-up.

FIGS. 6A-6B are cutaway side views of an example in-process substrate, in accordance with some embodiments. Referring to FIG. 6A, in some embodiments, electrodes 226A are printed on the bottom of the in-process substrate (e.g., by printing element 152 of FIG. 1A). Electrodes 226A may be printed silver. Referring to FIG. 6B, in some embodiments, the in-process substrate is flipped (e.g., by substrate flipper 188 of FIG. 1A). Electrodes 226B may be printed on the top of the in-process substrate (e.g., by printing element 154 of FIG. 1A). Electrodes 226B may be printed silver.

FIGS. 7A-7B are cutaway side views of an example in-process substrate, in accordance with some embodiments. Referring to FIG. 7A, in some embodiments, the in-process substrate is placed in a tray 720. A mask layer 742 may be placed over the electrodes 226B and/or the edges of the tray 720. Referring to FIG. 7B, in some embodiments, a TFE layer 228 may be deposited on the in-process substrate. The TFE layer 228 may encapsulate the top and/or sides of the in-process substrate. In some embodiments, the mask layer 742 can then be removed and the tandem cell structure may be finished.

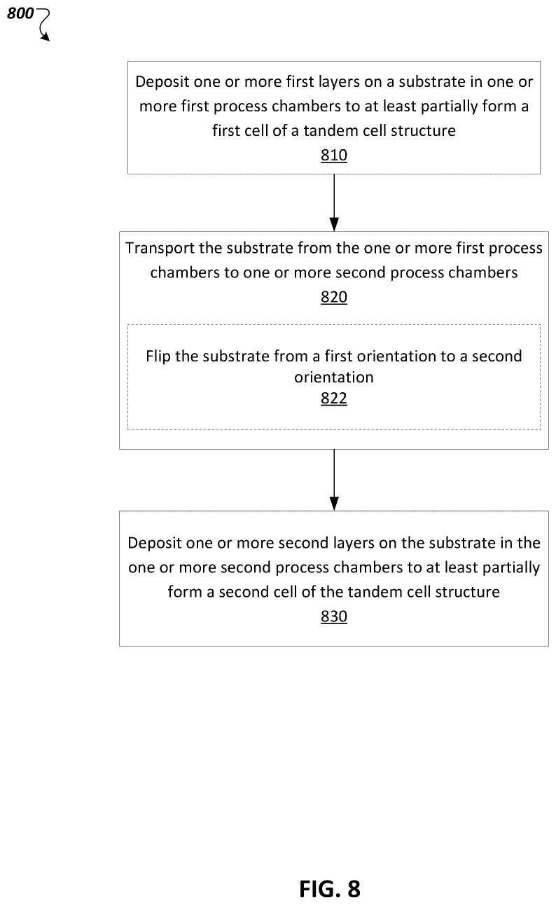

FIG. 8 is a flow chart of an example method 800 for processing a substrate, in accordance with some embodiments. The method may be performed by a system that may include hardware (circuitry, dedicated logic, etc.), computer-readable instructions (run on a general purpose computer system or a dedicated machine), or a combination of both. In an illustrative example, method 800 may be performed by a substrate processing system as described herein, such as system 100A of FIG. 1A and/or system 100B of FIG. 1B. It should be noted that blocks depicted in FIG. 8 could be performed simultaneously or in a different order than that depicted.

At block 810, a system (e.g., system 100A of FIG. 1A or system 100B of FIG. 1B) deposits one or more first layers on a substrate. The one or more first layers may be deposited directly on the substrate and/or on each other. The one or more first layers may be deposited on the substrate in one or more first process chambers. The one or more first process chambers may be a part of one or more first clusters of process chambers, each cluster including multiple process chambers. In some embodiments, each layer is deposited in a separate process chamber. In some embodiments, some layers are deposited in the same process chamber either sequentially or simultaneously. The one or more layers deposited on the substrate in the one or more first process chambers may at least partially form a first cell of a tandem cell structure.

At block 820, the system transports the substrate from the one or more first process chambers to one or more second process chambers. The one or more second process chambers may be a part of one or more second clusters of process chambers. The system may transport the substrate by a substrate transport sub-system, such as a conveyor, an overhead substrate delivery system, a substrate transport robot, and/or a maglev system. In some embodiments, the substrate is transported in a substrate carrier. The carrier may include slots and/or pockets for carrying multiple substrates. In some embodiments, transporting the substrate from the one or more first process chambers to the one or more second process chambers includes unloading the substrate from a first substrate carrier and loading the substrate into a second substrate carrier.

At block 822, the system may flip the substrate from a first orientation to a second orientation. In some examples, the substrate is flipped to an upside-down orientation and/or to a topside-up orientation. Flipping the substrate may allow for deposition processes to be carried out with respect to one side of the substrate or to the other side of the substrate. For example, after depositing a layer on the top side of the substrate, the substrate may be flipped so a layer can be deposited on the bottom side of the substrate. In some embodiments, the substrate is flipped by a substrate flipper such as a substrate flipping robot. The substrate flipper may be configured to flip multiple substrates at once.

At block 830, the system deposits one or more second layers on the substrate. The one or more second layers maybe deposited on the one or more first layers, directly on the substrate, and/or on each other. The one or more second layers may be deposited on the substrate in the one or more second process chambers. The one or more second process chambers may be a part of a combination cluster of process chambers having multiple process chambers to perform multiple substrate processing procedures. In some embodiments, each layer is deposited in a separate process chamber. In some embodiments, some layers are deposited in the same process chamber either sequentially or simultaneously. The one or more second layers deposited on the substrate in the one or more second process chambers may at least partially form a second cell of the tandem cell structure. In some embodiments, the second cell is disposed on top of the first cell to form the tandem cell structure.

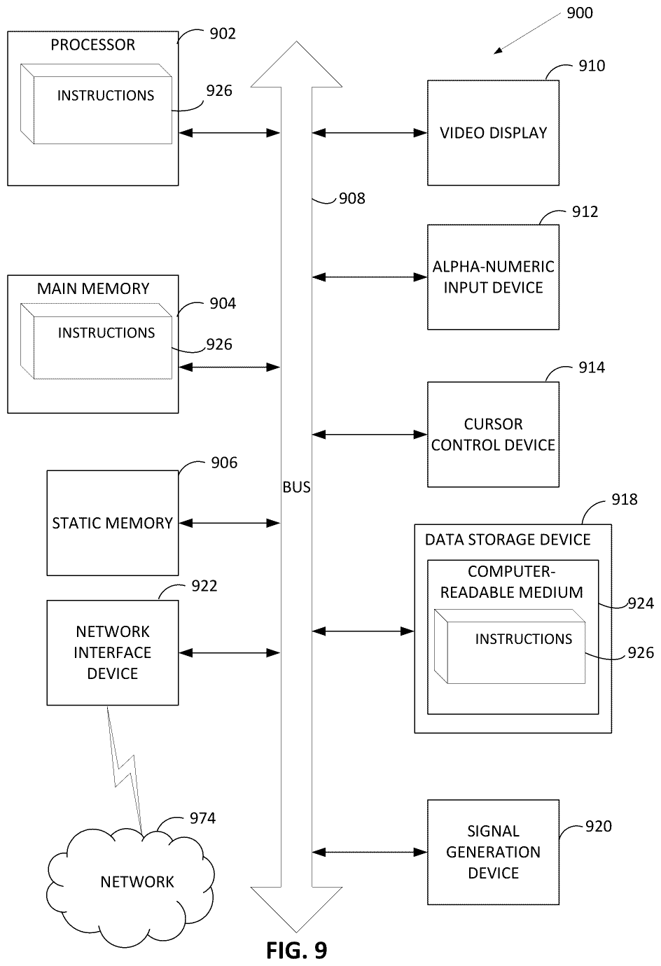

FIG. 9 is a block diagram illustrating a computer system 900, in accordance with some embodiments. In some embodiments, computer system 900 is connected (e.g., via a network, such as a Local Area Network (LAN), an intranet, an extranet, or the Internet) to other computer systems. In some embodiments, computer system 900 operates in the capacity of a server or a client computer in a client-server environment, or as a peer computer in a peer-to-peer or distributed network environment. In some embodiments, computer system 900 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 900 includes a processing device 902, a volatile memory 904 (e.g., Random Access Memory (RAM)), a non-volatile memory 906 (e.g., Read-Only Memory (ROM) or Electrically-Erasable Programmable ROM (EEPROM)), and a data storage device 916, which communicate with each other via a bus 908.

In some embodiments, processing device 902 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 900 further includes a network interface device 922 (e.g., coupled to network 974). In some embodiments, computer system 900 also includes a video display unit 910 (e.g., an LCD), an alphanumeric input device 912 (e.g., a keyboard), a cursor control device 914 (e.g., a mouse), and a signal generation device 920.

In some implementations, data storage device 916 includes a non-transitory computer-readable storage medium 924 on which store instructions 926 encoding any one or more of the methods or functions described herein. For example, the instructions 926 can include instructions for controlling the movement of the stage and/or digital lithography exposure units (“exposure units”) of a digital lithography system, which, when executed, can implement the methods for performing exposure unit scan sequencing described herein.

In some embodiments, instructions 926 also reside, completely or partially, within volatile memory 904 and/or within processing device 902 during execution thereof by computer system 900, hence, in some embodiments, volatile memory 904 and processing device 902 also constitute machine-readable storage media.

While computer-readable storage medium 924 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as ASICS, FPGAs, DSPs or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “training,” “identifying,” “further training,” “re-training,” “causing,” “receiving,” “providing,” “obtaining,” “optimizing,” “determining,” “updating,” “initializing,” “generating,” “adding,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A substrate processing system comprising:
two or more process tools comprising a plurality of process chambers configured to perform a corresponding substrate processing procedure;
a substrate transport configured to transport substrates between the two or more process tools; and
a control system to:
cause one or more first layers to be deposited on a substrate in one or more first process chambers of the two or more process tools to at least partially form a first cell of a tandem cell structure;
cause the substrate to be transported from the one or more first process chambers to one or more second process chambers of the two or more process tools, wherein a combination process tool of the two or more process tools comprises the one or more second process chambers; and
cause one or more second layers to be deposited on the substrate in the one or more second process chambers to at least partially form a second cell of the tandem cell structure.

2. The substrate processing system of claim 1, further comprising:
a metal printing sub-system configured to deposit a metal layer on substrates, wherein the control system is further to:
cause one or more first metal electrodes to be deposited by the metal printing sub-system on a first side of the substrate and one or more second metal electrodes to be deposited by the metal printing sub-system on a second side of the substrate.

3. The substrate processing system of claim 1, wherein the plurality of process chambers are each configured to deposit a respective layer on the substrate by chemical vapor deposition (CVD), by physical vapor deposition (PVD), or by evaporation.

4. The substrate processing system of claim 1, wherein the control system is further to:
cause the substrate to be flipped from a first orientation to a second orientation while being transported between at least two of the two or more process tools.

5. The substrate processing system of claim 1, wherein the one or more second process chambers comprises:
a first process chamber configured to deposit a first layer of the one or more second layers on the substrate by a first deposition procedure;
a second process chamber configured to deposit a second layer of the one or more second layers on the substrate by a second deposition procedure;
a third process chamber configured to deposit a third layer of the one or more second layers on the substrate by a third deposition procedure; and
a fourth process chamber configured to deposit a fourth layer of the one or more second layers on the substrate by a fourth deposition procedure.

6. The substrate processing system of claim 5, wherein the control system is further to:
cause a perovskite layer to be deposited on the substrate in one of the one or more second process chambers.

7. The substrate processing system of claim 5, wherein at least one of the first deposition procedure, the second deposition procedure, the third deposition procedure, or the fourth deposition procedure comprises evaporation.

8. The substrate processing system of claim 5, wherein the combination process tool is configured to handle the substrate in a vertical orientation.

9. The substrate processing system of claim 1, further comprising a substrate tray comprising a gridded structure configured to support one or more substrates along one or more edges of the one or more substrates.

10. The substrate processing system of claim 9, wherein the substrate tray comprises an electrostatic chuck configured to retain multiple substrates on the substrate tray responsive to activation of the electrostatic chuck.

11. The substrate processing system of claim 1, wherein the tandem cell structure comprises the second cell disposed on top of the first cell.

12. The substrate processing system of claim 1, wherein transporting the substrate from the one or more first process chambers to the one or more second process chambers comprises:
unloading the substrate from a first carrier configured to carry multiple substrates; and
loading the substrate into a second carrier configured to carry multiple substrates.

13. A system comprising:
one or more first process chambers configured to deposit one or more first layers on a substrate to at least partially form a first cell of a tandem cell structure;
one or more second process chambers configured to deposit one or more second layers on the substrate to at least partially form a second cell of the tandem cell structure; and
a substrate transport configured to transport the substrate between the one or more first process chambers and the one or more second process chambers.

14. The system of claim 13, further comprising:
a metal printing sub-system configured to deposit one or more first metal electrodes on a first side of the substrate and one or more second metal electrodes on a second side of the substrate.

15. The system of claim 13, wherein the one or more first process chambers and the one or more second process chambers are configured to perform one of a chemical vapor deposition (CVD) procedure, a physical vapor deposition (PVD) procedure, or an evaporation deposition procedure.

16. The system of claim 15, wherein one of the second process chambers is configured to deposit a perovskite layer on the substrate.

17. The system of claim 1, wherein transporting the substrate from the one or more first process chambers to the one or more second process chambers comprises:
unloading the substrate from a first carrier configured to carry multiple substrates;
flipping the substrate from a first orientation to a second orientation; and
loading the substrate into a second carrier configured to carry multiple substrates.

18. A method comprising:
depositing one or more first layers on a substrate in one or more first process chambers to at least partially form a first cell of a tandem cell structure;
transporting the substrate from the one or more first process chambers to one or more second process chambers; and
depositing one or more second layers on the substrate in the one or more second process chambers to at least partially form a second cell of the tandem cell structure.

19. The method of claim 18, wherein the tandem cell structure comprises the second cell disposed on top of the first cell.

20. The method of claim 18, further comprising:
depositing a perovskite layer on the substrate in one of the one or more second process chambers.
